(19) United States
(12) Patent Application Publication
(10) Pub. No.: US 2017/0065927 A1
(43) Pub. Date: Mar. 9, 2017

(54) COATED MOLECULAR SIEVE

(71) Applicants: Nanoscape AG, Planegg (DE); Saes Getters S.p.A., Milano (IT)

(72) Inventors: Jurgen Sauer, Planegg (DE); A. Kohl, Planegg (DE)

(73) Assignees: Nanoscape AG, Planegg (DE); Saes Getters S.p.A., I Milano (IT)

(21) Appl. No.: 15/273,339

(22) Filed: Sep. 22, 2016

Related U.S. Application Data
(63) Continuation of application No. 12/305,525, filed on Dec. 2, 2009.

(30) Foreign Application Priority Data
Jun. 27, 2006 (DE) 10 2006 029 849.7

(51) Int. Cl. B01D 53/04; B01J 20/22; B81B 7/00; B01J 20/32; B01D 53/26; H01L 51/52; B01J 20/18; B01J 20/28

(52) U.S. Cl. CPC B01D 53/0407; B01J 20/183; B01J 20/22; B01J 20/28016; B01J 20/28026; B01J 20/3204; B01J 20/3257; B01J 20/3293; B01D 53/261; H01L 51/5259; B81B 7/0038; B01D 2257/80; B01D 2253/20; B01D 2253/25; B01D 2253/304

(57) ABSTRACT

The invention relates to a hydrophobically coated molecular sieve which comprises particles having a particle size of 1000 nm or less, the surface of the particles being coated with a silane of the general formula SiR¹R²R³R⁴, and also to a method of producing it and to a method of using it. In addition, the invention relates to use of the coated molecular sieve and also to compositions comprising the molecular sieve and to use in producing apparatus such as, for example, electronic components and devices.

The present invention relates to a coated molecular sieve and to a method of preparing it. In addition, the invention relates to use of the coated molecular sieve and to compositions comprising the molecular sieve. The present invention further relates to use of the molecular sieve and of compositions comprising the molecular sieve in the production of apparatus, for example electronic components and devices, and also to apparatus, for example electronic components and devices, comprising the molecular sieve. The present invention relates especially to a hydrophobically coated molecular sieve and to a method of producing it. In addition, the invention relates to use of the hydrophobically coated molecular sieve and to compositions comprising the hydrophobically coated molecular sieve. The present invention further relates to use of the hydrophobically coated molecular sieve and of compositions comprising the hydrophobically coated molecular sieve in the production of apparatus, for example electronic components and devices, and also to apparatus, for example electronic components and devices, comprising the molecular sieve.

### BACKGROUND TO THE INVENTION

Modern electrical and electronic components and devices often comprise materials or substances which are sensitive to gaseous molecules from the ambient atmosphere, for example oxygen or water vapour, because they are attacked as a result of the action of those molecules and, for example, may be destroyed as a result of corrosion or hydrolysis. A customary method of protecting such materials in components and devices is provided by encapsulation wherein the components or devices are hermetically sealed off from the environment. In this context, it is also customary to incorporate so-called “getters” in the interior of the encapsulated components or devices which are capable of catching those gas molecules that do nevertheless penetrate inside.

Customary getter materials are substances which are able to bind small molecules, for example gas molecules or water, by means of a chemical reaction (“absorption”) or to physically take them up (“adsorption”). Getter materials in current use are metals or metal alloys or molecular sieves. Such getter materials which are used to protect materials or components from the damaging influence of moisture (water) or gases, for example oxygen, are described, inter alia, in DE 3218625 A1, DE 3511323 A1 or DE 3101128 A1.

Besides incorporating a getter material in the interior of an encapsulated component or device it is also possible to incorporate getter materials in organic materials which are used to seal the sensitive materials inside the components or devices or to seal the components or devices themselves. For example, the getter materials can be incorporated in organic polymers, adhesives or surface-coating compositions which are then used to encapsulate a component or device, to adhesively bond a casing thereof or to cover it with a coating. An adhesive composition having barrier properties is disclosed in DE 10344449 A1, and DE 19853971 A1 describes inorganic/organic polysiloxane hybrid polymers. Furthermore, US 2004/0132893 A1 discloses a mouldable paste comprising a zeolite, an organic binder and a solvent, which paste is used in the preparation of a getter. U.S. Pat. No. 5,401,536 describes, for producing a moisture-free sealed enclosure of an electronic apparatus, a coating and an adhesive which consist of a protonated aluminosilicate powder and a polymer. All those compositions comprise getter materials which are embedded more or less coarsely, but not homogeneously dispersed, in a matrix (pastes). None of those compositions allows transparent layers to be produced and also they cannot be used in a printing process.

In recent years an increasing trend towards miniaturisation of many electrical and electronic devices has been seen. This ongoing miniaturisation is giving rise to many problems, not least with respect to protecting sensitive materials, components or devices against moisture or other damaging gas molecules from the ambient atmosphere. On the one hand, the amounts of the sensitive materials that have to be protected are becoming ever smaller so that even a relatively small number of gas molecules is sufficient to damage them. The protection must therefore be so good that, as far as possible, not a single damaging gas molecule reaches the sensitive material. On the other hand, the space that is available inside an encapsulated component or device is becoming ever smaller so that a getter should as far as possible be in a small form so that it can be used in apparatus of such dimensions. Even if a getter is to be incorporated in a sealing or covering layer for sealing a component or device of such dimensions, the getter should be in a form that is as small as possible, because not only is the thickness of a layer protecting a component or material dropping but so too are the dimensions in terms of area (width and depth), limiting the possible particle size of a getter material so that the use of customary getter materials having a particle size in the region of some micrometres can be disadvantageous or unfeasible. In particular in the course of the currently rapidly ongoing miniaturisation of electronic components such as, for example, MEMS devices, and the ever smaller dimensions of, for example, electro-optical devices containing them, the use of customary getter materials is now possible to only a limited extent because of the fact that they are present in particles having a size of usually some micrometres.

When composite materials comprising a polymer, a surface-coating composition or an adhesive and a getter material are to be used for encapsulating sensitive materials, substances, components or devices, a getter material can protect the material, component or device especially effectively if the individual particles are small compared to the thickness of the layer consisting of the composite material and if they are homogeneously distributed. If the particles are too large compared to the thickness of the composite layer, passageways for gas or water can be formed at locations where, because of the statistical distribution of the getter particles in the layer, no particle is present, as shown in FIG. 1. On the other hand, passageways for gas or water can also be formed at locations where accumulations or agglomerates of getter particles occur, as shown in FIG. 2. For that reason, a getter material should have good dispersibility in the organic compounds together with which it is present in the composite material. The poor dispersibility in many organic compounds which are customarily used for sealing purposes such as, for example, polymers, adhesives, surface-coating compositions or the like is a further disadvantage of customary getter materials.

For example, customary getter materials such as, for example, zeolites have only poor dispersibility in nonpolar media as many polymers, adhesives, surface-coating compositions, solvents and the like are. In general, oxidic materials, which also include the zeolites, are poorly dispersible in nonpolar solvents but in contrast have good dispersibility in water, aqueous acids and bases. The reason for that behaviour lies in the surface chemistry of that class of materials. The external surface of oxidic materials, which also include the zeolites, usually terminates in OH groups [Nature and Estimation of Functional Groups on Solid Surfaces, H. P. Boehm, H. Knözinger, Catalysis Science and Technology, Vol. 4, Springer Verlag, Heidelberg, 1983]. When an oxide is dispersed in water, a diversity of interactions between those OH groups and water come about. Hydrogen bridge bonds can be formed, resulting in a water layer that adheres to the oxide. The existence of such an adhering water layer on the oxide can result in its being possible to obtain the oxide in the form of a stable aqueous suspension, because the oxide particles cannot come into contact with one another and therefore cannot agglomerate either. Depending on the pH of a solution, a zeolite can lose or gain protons as a result of some of the OH groups located on the surface losing or gaining a proton. The OH group in question is then present as an O⁻ centre or an OH₂⁺ group. Additional charges on the oxide result in further stabilisation of an aqueous suspension because particles that approach one another are subject to repulsive forces and therefore cannot come into contact with one another or agglomerate or form clumps.

However, in a nonpolar environment, for example in organic solvents such as, for example, hexane, toluene or petroleum ether, or liquid, melted polymers of low polarity such as, for example, polyethylene, the mentioned interactions between the oxide surface and the solvent cannot come about because the solvent molecules are not able to form hydrogen bridge bonds. In addition, charges are not stabilised by the molecules of low polarity. This means that the surface of oxides in nonpolar solvents is charged only to the very slightest of extents. Repulsive forces between the oxide particles are therefore not present or are present only to a very small extent. Oxidic substances in nonpolar solvents therefore form into agglomerates and clumps, as shown in FIG. 3. In this case, a condensation reaction of the OH groups present on the surface often takes place, so that irreversible growth of the particles into one another takes place and accordingly large agglomerates are formed. These agglomerates can no longer be dispersed.

In order to be able to disperse oxidic particles in nonpolar solvents, the OH groups located at the surface of the oxide in question can be functionalised with organic groups which are as similar as possible to the solvent in question. Such surface coatings are described, for example, in DE 10319 937 A1.

The surface of the oxide particles can thereby be coated with nonpolar and covalently bonded groups. The formation of a covalent, chemically resistant bond is desirable because a loss of nonpolar groups can result in the particles having an increased agglomeration tendency. Preference is given to the formation of a durable covalent bond over ionic bonds as are described, for example, in “The surface modification of zeolite-4A by CTMAB and its properties”, L. Guo, Y. Chen, J. Yang, Journal of Wuhan University of Technology, Materials Science and Engineering, Wuhan University of Technology, Materials Science Edition (1999), 14(4), 18-23, because ionic bonds, which are based on the formation of ion pairs, can be readily broken apart by other ions.

No condensation reactions can take place between the slow-to-react organic groups on the surface of a particle coated in that manner. Interactions between particles are therefore based mainly on van der Waals forces. This means that if two particles come into contact with one another, they are unable to durably and irreversibly agglomerate. Such functionalised oxides have good dispersibility in nonpolar solvents.

Customary reagents for the purpose of functionalisation are chlorosilanes such as, for example, trimethylchlorosilane (TMSCl) or also diethyldichlorosilane. Zeolite powders surface-modified using alkylhalosilanes are described, for example, in EP 1 020 403 A1. When an oxide is reacted with a reagent of such a kind, hydrogen chloride is split off and a covalent bond is formed between the silane radical and the surface of the oxide, as shown in FIG. 4. However, these reagents have the disadvantage that the getter material can be attacked by the corrosive hydrogen chloride molecules. Investigations by the inventors of the present invention have shown that, in particular, alkylhalosilanes destroy the structure of zeolite particles; the smaller the particles the more pronounced is the effect because of the increase in the relative external surface area of those particles. Generally, porous particles suffer especially from that destruction, probably because they are attacked by the corrosive halogen compounds not only from the outside but also, at the same time, from the inside. When halosilane reagents are used it is also disadvantageous that, when porous particles are being coated, the pores, internal channels and cavities of the particles can become coated and/or blocked or plugged. Systems in which the internal surface is neither coated nor blocked and so retains its original character, as shown in FIG. 5, are desirable.

Therefore, oxidic getter materials such as, for example, zeolites are also reacted with alkoxysilanes in order to silanise the external surface, as described in “Surface organometallic chemistry on zeolites: a tool for modifying the sorption properties of zeolites” A. Choplin, Journal of Molecular Catalysis (1994), 86(1-3), 501-512. However, zeolites modified in that manner are described therein solely as an intermediate for further modification. This is possible especially because zeolites so modified have similar surface properties to non-modified zeolites, as are described hereinbefore. In the process there are used, especially, silane-coupling agents which are capable of cross-linking with one another in aqueous media. This effect is utilised, for example in the case of the zeolite particles coated with the silane-coupling agents aminopropyltrimethoxysilane or glycidyloxypropyltrimethoxysilane, which are described in DE 100 56 362 A1, in order to stabilise a colloidal aqueous suspension of zeolite particles. A process for the production of zeolite surface-modified in such a manner and the use thereof in detergents and cleansing agents is described in EP 0 088 158 A1. Those surface-modified zeolites are, according to their use, hydrophilic particles which can accordingly be dispersed non-homogeneously in lipophilic organic compounds such as, for example, alkanes.

Customary zeolites usually have a particle size of some micrometres (see, for example, the information brochure “Dessipaste™” of the company Südchemie AG) and may be coated as described, for example, in “Silylation of micro-, meso-, and non-porous oxides: a review”; N. Impens; P. Van der Voort; E. Vansant; Microporous and Mesoporous Materials (1999), 28(2), 217, or in “Chemical modifications of oxide surfaces”; P.Cool; E. Vansant; Trends in physical Chemistry (1999), 7, 145-158. Those sources do not, however, describe dispersion properties of those coated zeolite particles in polymers or, more generally, in nonpolar media. Use of coated zeolites as getter materials in thin layers is also not described.

A further disadvantage of using customary getter materials in polymers is the possibility of the polymer being made cloudy by scattering processes caused by getter particles having a refractive index differing from that of the polymer and an average size far above the Mie scattering limit of about 40 nm for visible light. If transparent layers are to be produced, as are required, for example, for encapsulating solar cells or OLEDs, such cloudiness must be avoided, or should be as low as possible.

A further disadvantage of customary getters is that, because of their size, they are not compatible with customary methods for the production of miniaturised electronic components and devices. Such apparatus is nowadays usually printed onto suitable surfaces by machine using automatic apparatus such as, for example, printing or spraying apparatus. The printing nozzles used therein have an internal diameter in the region of some micrometres. For that reason, getter-containing liquids that are to be processed must contain not only no particles having a size larger than the internal diameter of the nozzle but also no agglomerates of solids which might block the nozzle.

### BRIEF DESCRIPTION OF THE INVENTION

The problem for the invention described hereinbelow was to overcome the mentioned disadvantages of customary materials.

The invention should especially provide a molecular sieve which is small enough to be used in miniaturised apparatus, whilst it should also be suitable for homogeneous dispersion in organic compounds, especially nonpolar organic compounds. The molecular sieve should also be suitable for producing transparent layers. Furthermore, the molecular sieve should be suitable for processing in a printing method.

After intensive studies, the inventors of the present invention have found that the problem for the invention is solved by a molecular sieve, especially a hydrophobically coated molecular sieve, which comprises particles having a particle size of 1000 nm or less, the surface of the particles being coated with a silane of the general formula

SiR¹R²R³R⁴

at least one of the radicals R¹, R², R³ or R⁴ containing a hydrolysable group, and the remaining radicals R¹, R², R³ and R⁴ being, independently of one another, an alkyl, alkenyl, alkynyl, heteroalkyl, cycloalkyl, heteroaryl, alkylcycloalkyl, hetero(alkylcycloalkyl), heterocycloalkyl, aryl, arylalkyl or hetero(arylalkyl) radical.

### DESCRIPTION OF THE FIGURES

FIG. 1 shows, in diagrammatic form, the structure of two layer-systems comprising (a) an organic polymer and (b) getter particles.

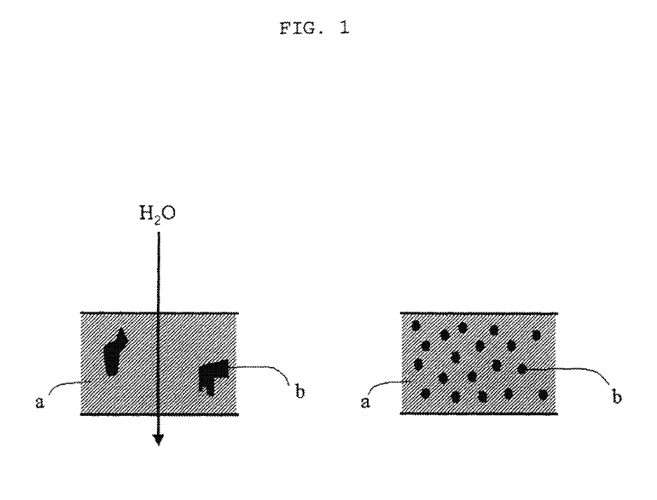

FIG. 2 shows, in diagrammatic form, a layer comprising a) polymer and b) getter particles which form a cluster (c). The arrow included in the drawing marks the quickest route for water diffusing in.

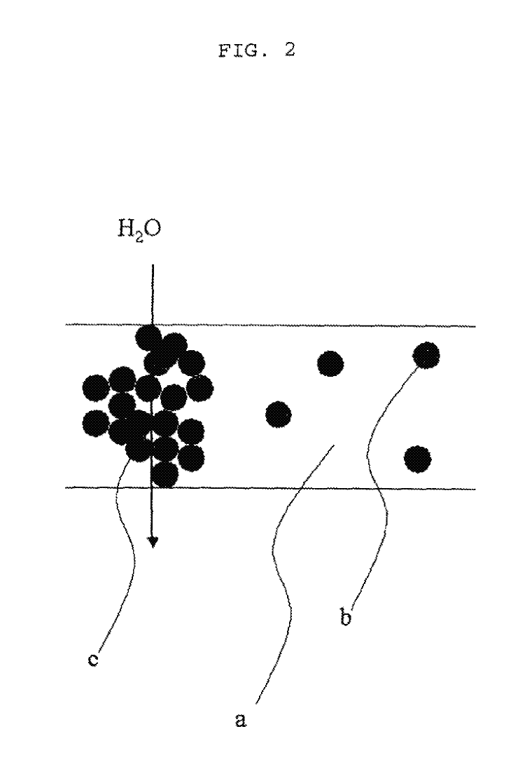

FIG. 3 shows, in diagrammatic form, the clumping of oxidic particles having surface OH groups. a) denotes the interior of an oxidic particle.

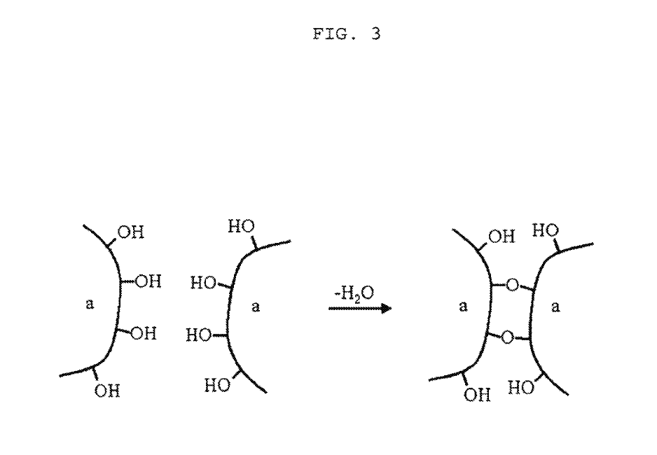

FIG. 4 shows, in diagrammatic form, the hydrophobicisation of oxidic particles having surface OH groups. a) denotes the interior of an oxidic particle.

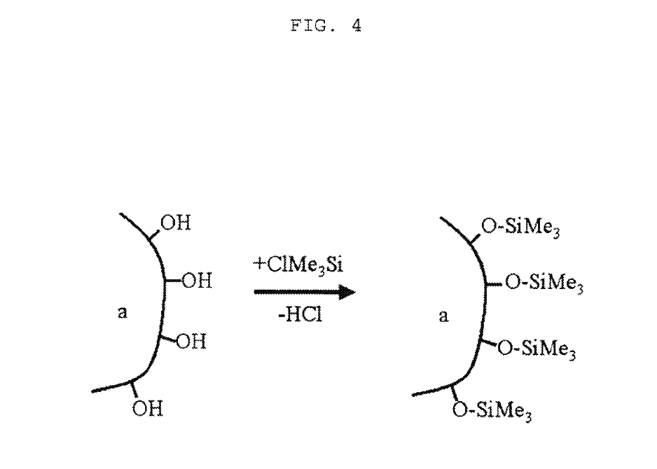

FIG. 5 shows, in diagrammatic form, the hydrophobicisation of oxidic particles having a pore structure. a) denotes the interior of an oxidic particle.

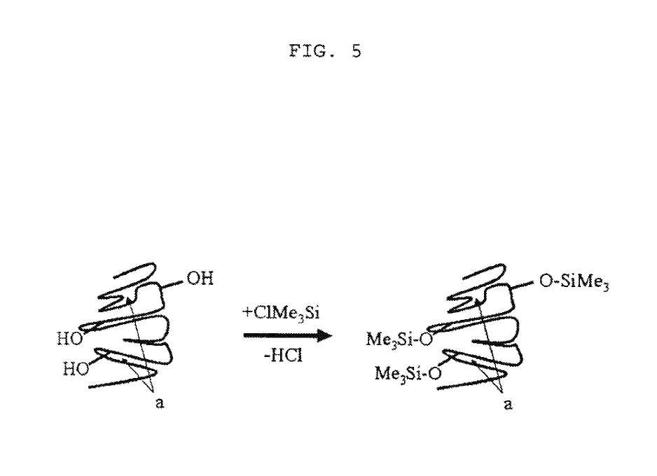

FIG. 6 shows, in diagrammatic form, a multi-layer structure which consists of alternating barrier layers (a) and polymer/molecular sieve composite (b).

FIG. 7 shows a typical size distribution for the particles of zeolite LTA used in the Examples. The mass distribution is plotted against the particle diameter in nm.

FIG. 8 shows, in diagrammatic form, the set-up for a water permeation test, wherein a) denotes a paper impregnated with anhydrous, blue cobalt chloride, b) denotes a polymer layer and c) denotes water.

FIG. 9 shows photographs which record the results of investigation of the barrier property of a composite material using cobalt chloride (water permeation test). In the photographs, anhydrous, blue cobalt chloride appears as dark grey, and aqueous, pink cobalt chloride appears as light grey. The top row shows a comparison sample, and the bottom row shows a sample according to the invention, in each case at the start of the test (3 minutes) and after 28 and 100 minutes.

FIG. 10 shows the result of investigation of the properties of surface-coating compositions comprising the molecular sieve according to the invention, by means of a calcium mirror test.

### DETAILED DESCRIPTION OF THE INVENTION

The invention relates to a hydrophobically coated molecular sieve, which comprises particles having a particle size of 1000 nm or less, the surface of the particles being coated with a silane of the general formula

SiR¹R²R³R⁴,

at least one of the radicals R¹, R², R³ or R⁴ containing a hydrolysable group, and the remaining radicals R¹, R², R³ and R⁴ being, independently of one another, an alkyl, alkenyl, alkynyl, heteroalkyl, cycloalkyl, heteroaryl, alkylcycloalkyl, hetero(alkylcycloalkyl), heterocycloalkyl, aryl, arylalkyl or hetero(arylalkyl) radical.

In a preferred embodiment, at least one of the radicals R¹, R², R³ or R⁴ contains a hydrolysable group which is selected from an alkoxy group and a cyanide group.

In this context, the expression “molecular sieve” means especially a compound which is able to bind small molecules. The expression “small molecules” in this context refers, for example, to molecules of from two to twelve atoms, preferably of from two to six atoms, and especially two to three atoms. These molecules may under normal conditions be in the form of a gas, which may, for example, be found in the ambient atmosphere. Preferred examples of such molecules are gases contained in air such as, for example, oxygen (O₂) or also water (H₂O). The binding of the molecules by the molecular sieve is generally reversible or irreversible, and is preferably reversible. The molecular sieves are preferably porous compounds which are capable of binding small molecules not only on their surface but also in the interior of their pores. Preferred examples of such molecular sieves are, for example, classic oxidic solids or modern hybrid materials.

In this context, the expression “oxidic solid” means, especially, an inorganic compound which is present in the form of a crystalline, partially crystalline or non-crystalline solid. Besides metal cations, including cations of one or more elements of the main groups or sub-groups of the periodic system, an oxidic solid of such a kind includes anions comprising oxygen atoms. Preferred examples of such anions, besides the oxide anion (O²⁻), the hyperoxide anion (O₂⁻) and the peroxide anion (O₂²⁻), are also anions which are based on oxides of elements of the main groups and sub-groups such as, for example, sulfur oxide anions, phosphate anions, silicate anions, borate anions, aluminate anions, tungstate anions and the like. Such anions can be present, for example, in isolated form or be condensed in the form of, for example, chains, bands, layers, frameworks, cages or the like. Condensed anions of such a kind may include oxides of one or more elements of the main groups and sub-groups, with its being possible for a plurality of different elements to be included in one condensed anion.

The expression “hybrid material” means especially a compound containing elements which are conventionally allocated not only to inorganic chemistry but also to organic chemistry. Preferred examples of hybrid materials of such a kind are, for example, organometallic compounds which include, besides metal atoms, organic molecules bonded thereto. In this context the bonding between the metal atom and organic molecule can be ionic or covalent. The constituents of such compounds can be linked together in two or three dimensions, for example to form chains, bands, columns, layers, frameworks, cages and the like. Depending on the nature of their constituents and their bonding, such compounds can be in the form of solids having rigid or flexible properties. Preferred examples are compounds from the class of organometallic polymers or those from the class of the so-called MOF (metal organic framework) compounds. Preferred examples of hybrid materials of such a kind are, for example, compounds which include transition metal elements such as, for example, copper or zinc and organic molecules having two or more functions which are suitable for the formation of a bond with a metal atom, such as, for example, a carboxylic acid function, an amine function, a thiol function and the like, on an organic chain or on an organic framework or in an organic ring system such as, for example, a pyridine, piperidine, pyrrole, indole or pyrazine ring or the like. Preferred examples are, for example, hybrid compounds of zinc and α,ω-dicarboxylic acids having a long-chain (C6-C18) hydrocarbon backbone, or compounds of zinc and nitrogen-containing ring systems substituted with carboxylic acid functions. Such compounds can be obtained in the form of three-dimensional solids and are able to bind small molecules, such as, for example, MOF-5, described in H. Li et al., Nature 402 (1999), 276.

The expression “particles” means, especially, individual particles or small parts of molecular sieve which are present preferably in the form of discrete particles. The particles may be present in the form of a monocrystal or may themselves comprise agglomerated smaller, crystalline or non-crystalline particles which are fixedly connected to one another. For example, the individual particles may be present in the form of a mosaic compound consisting of smaller monocrystallites. The particles may be present in a round shape, for example spherical, oviform or in the shape of an ellipsoid or the like, or in an angular shape, for example in the shape of cubes, parallelepipeds, flakes or the like. Preferably, the particles are spherical.

The expression “particle size” herein means the maximum diameter of a particle. The expression is used herein both for the maximum diameter of an uncoated particle and for the maximum diameter of a silane-coated particle, but especially for the maximum diameter of a coated particle. The particle size of a particle is determined, for example, by conventional methods using the principle of dynamic light scattering. For that purpose, the particles are suspended or dispersed in a suitable inert solvent and measured using a suitable measuring device. The size of the particles can also be determined by measurement using SEM (scanning electron microscope) images. The individual particles are preferably spherical. The particle size of the particles is 1000 nm or less, preferably 800 nm or less, more preferably 600 nm or less, even more preferably 400 nm or less, even more preferably 300 nm or less, even more preferably 200 nm or less, even more preferably 100 nm or less, even more preferably 40 nm or less, and especially 26.6 nm or less. The minimum particle size is 2 nm or more, preferably 5 nm or more, more preferably 10 nm or more, and especially 15 nm or more.

The expression “hydroxide radical” means the group —OH.

The expression “alkyl radical” means a saturated, straight-chain or branched hydrocarbon group, which has especially from 1 to 20 carbon atoms, preferably from 1 to 12 carbon atoms, more preferably from 1 to 8 and very preferably from 1 to 6 carbon atoms, for example the methyl, ethyl, propyl, isopropyl, n-butyl, isobutyl, sec-butyl, tert-butyl, n-pentyl, isopentyl, neopentyl, sec-pentyl, tert-pentyl, n-hexyl, 2,2-dimethylbutyl or n-octyl group. Even greater preference is given to the alkyl radical being a branched hydrocarbon group having from 3 to 8 carbon atoms, especially from 3 to 6 carbon atoms, for example an isopropyl, isobutyl, sec-butyl, tert-butyl, isopentyl, neopentyl, sec-pentyl, tert-pentyl or 2,2-dimethylbutyl group. The use of silanes having branched alkyl radicals advantageously results in the molecular sieve according to the invention having a high degree of hydrophobicity. This is presumably caused by good shielding of the hydrophilic molecular sieve surface from a solvent. An alkyl radical as understood by the invention is bonded to the central silicon atom of the silane by means of a silicon-carbon bond and is not hydrolysable.

The expressions “alkenyl radical” and “alkynyl radical” refer to at least partially unsaturated, straight-chain or branched hydrocarbon groups which have especially from 2 to 20 carbon atoms, preferably from 2 to 12 carbon atoms and very preferably from 2 to 6 carbon atoms, for example the vinyl or ethenyl, allyl, acetylenyl, propargyl, isoprenyl or hex-2-enyl group. Preference is given to alkenyl groups having one or two (especially one) double bond(s) and to alkynyl groups having one or two (especially one) triple bond(s). An alkenyl or alkynyl radical as understood by the invention is bonded to the central silicon atom of the silane by means of a silicon-carbon bond and is not hydrolysable.

Furthermore, the expressions “alkyl radical”, “alkenyl radical” and “alkynyl radical” refer to groups in which, for example, one or more hydrogen atom(s) has/have been replaced in each case by a halogen atom (fluorine, chlorine, bromine or iodine) or by one or more, possibly different, group(s) —COOH, —OH, —SH, —NH₂, —NO₂, ═O, ═S, ═NH, for example by the chloromethyl, bromomethyl, trifluoromethyl, 2-chloroethyl, 2-bromoethyl, 2,2,2-trichloroethyl or heptadecafluoro-1,1,2,2-tetrahydrodecyl group.

The expression “heteroalkyl radical” refers to an alkyl, alkenyl or alkynyl radical in which one or more (preferably 1, 2 or 3) carbon atom(s) has/have been replaced by an oxygen, nitrogen, phosphorus, boron, selenium, silicon or sulfur atom (preferably oxygen, sulfur or nitrogen). The expression “heteroalkyl” refers furthermore to a group derived from a carboxylic acid, for example acyl, acylalkyl, alkoxycarbonyl, acyloxyalkyl, carboxyalkylamide or.

Preferred examples of heteroalkyl radicals are groups of the formulae R^{a}—O—Y^{a}—, R^{a}—S—Y^{a}—, R^{a}—N(R^{b})—Y^{a}—, R^{a}—CO—Y^{a}—, R^{a}—O—CO—Y^{a}—, R^{a}—CO—O—Y^{a}—, R^{a}—CO—N(R^{b})—Y^{a}—, R^{a}—N(R^{b})—CO—Y^{a}—, R^{a}—O—CO—N(R^{b})—Y^{a}—, R^{a}—N(R^{b})—CO—O—Y^{a}—, R^{a}—N(R^{b})—CO—N(R^{c})—Y^{a}—, R^{a}—O—CO—O—Y^{a}—, R^{a}—N(R^{b})—C(═NR^{d})—N(R^{c})—Y^{a}—, R^{a}—CS—Y^{a}—, R^{a}—O—CS—Y^{a}—, R^{a}—CS—O—Y^{a}—, R^{a}—CS—N(R^{b})—Y^{a}—, R^{a}—N(R^{b})—CS—Y^{a}—, R^{a}—O—CS—N(R^{b})—Y^{a}—, R^{a}—N(R^{b})—CS—O—Y^{a}—, R^{a}—N(R^{b})—CS—N(R^{c})—Y^{a}—, R^{a}—O—CS—O—Y^{a}—, R^{a}—S—CO—Y^{a}—, R^{a}—CO—S—Y^{a}—, R^{a}—S—CO—N(R^{b})—Y^{a}—, R^{a}—N(R^{b})—CO—S—Y^{a}—, R^{a}—S—CO—O—Y^{a}—, R^{a}—O—CO—S—Y^{a}—, R^{a}—S—CO—S—Y^{a}—, R^{a}—S—CS—Y^{a}—, R^{a}—CS—S—Y^{a}—, R^{a}—S—CS—N(R^{b})—Y^{a}—, R^{a}—N(R^{b})—CS—S—Y^{a}—, R^{a}—S—CS—O—Y^{a}—, R^{a}—O—CS—S—Y^{a}—, wherein R^{a} is a hydrogen atom, a C₁-C₆alkyl, C₂-C₆alkenyl or C₂-C₆alkynyl group; R^{b} is a hydrogen atom, a C₁-C₆alkyl, C₂-C₆alkenyl or C₂-C₆alkynyl group; R^{c} is a hydrogen atom, a C₁-C₆alkyl, C₂-C₆alkenyl or C₂-C₆alkynyl group; R^{d} is a hydrogen atom, a C₁-C₆alkyl, C₂-C₆alkenyl or C₂-C₆alkynyl group and Y^{a} is a direct bond, a C₁-C₆alkylene, C₂-C₆alkenylene or C₂-C₆alkynylene group, wherein each heteroalkyl group contains at least one carbon atom and one or more hydrogen atoms, independently of one another, may in each case have been replaced by a fluorine, chlorine, iodine or bromine atom. If the bond Y^{a} is between the silicon atom and a hetero atom such as, for example, nitrogen, oxygen or sulfur, that bond may generally be hydrolysed. Preferred examples of hydrolysable heteroalkyl radicals are, for example, alkoxy groups, e.g. methoxy, trifluoromethoxy, ethoxy, n-propyloxy, isopropyloxy and tert-butoxy. Further preferred examples of a hydrolysable heteroalkyl group are a nitrile group or cyanide group. A heteroalkyl radical which is bonded to the central silicon atom of the silane by a silicon-carbon bond is generally not hydrolysable. Specific examples of non-hydrolysable heteroalkyl radicals are methoxymethyl, ethoxymethyl, methoxyethyl, methylaminomethyl, ethylaminomethyl and diisopropylaminoethyl.

The expression “cycloalkyl radical” refers to a saturated or partially unsaturated (e.g. cycloalkenyl) cyclic group which has one or more rings (preferably 1, 2 or 3) forming a framework containing especially from 3 to 14 carbon atoms, preferably from 3 to 10 (especially 3, 4, 5, 6 or 7) carbon atoms. The expression “cycloalkyl” refers furthermore to groups in which one or more hydrogen atoms, independently of one another, has/have been replaced in each case by a fluorine, chlorine, bromine or iodine atom or by one of the groups —COOH, —OH, ═O, —SH, ═S, —HN₂, ═NH or —NO₂, for example non-hydrolysable cyclic ketones such as, for example, cyclohexanone, 2-cyclohexenone or cyclopentanone. A cycloalkyl radical according to the invention can be linked to the central silicon atom of the silane by way of a substituted group, for example —OH or —SH. Such a cycloalkyl radical is generally hydrolysable. Preferably, a cycloalkyl radical according to the invention is bonded to the central silicon atom of the silane by a silicon-carbon bond and is not hydrolysable. Preferred examples of non-hydrolysable cycloalkyl groups are the cyclopropyl, cyclobutyl, cyclopentyl, spiro[4,5]decanyl, norbornyl, cyclohexyl, cyclopentenyl, cyclohexadienyl, decalinyl, cubanyl, bicyclo[4.3.0]nonyl, tetraline, cyclopentylcyclohexyl, fluorocyclohexyl, cyclohex-2-enyl or adamantyl group.

The expression “heterocycloalkyl radical” refers to a cycloalkyl group as defined hereinbefore, in which one or more (preferably 1, 2 or 3) ring carbon atom(s) has/have been replaced by an oxygen, nitrogen, silicon, selenium, phosphorus or sulfur atom (preferably oxygen, sulfur or nitrogen). A heterocycloalkyl group preferably has 1 or 2 rings having from 3 to 10 (especially 3, 4, 5, 6 or 7) ring atoms. The expression “heterocycloalkyl radical” refers furthermore to groups in which one or more hydrogen atoms, independently of one another, has/have been replaced in each case by a fluorine, chlorine, bromine or iodine atom or by one of the groups —COOH, —OH, ═O, —SH, ═S, —NH₂, ═NH or —NO₂. If there is a direct bond between the silicon atom of the silane and a hetero atom, for example oxygen, nitrogen or sulfur, of the heterocycloalkyl radical, this bond, and as a result, the complete radical, can generally be hydrolysed. Preferably, a heterocycloalkyl radical according to the invention is bonded to the central silicon atom of the silane by a silicon-carbon bond and is not hydrolysable. Examples of a hydrolysable heterocycloalkyl radical are, for example, 1-piperazinyl, N-pyrrolidinyl or N-piperidyl, whilst, for example, 2-pyrrolidinyl or 3-piperidyl are examples of a non-hydrolysable heterocycloalkyl radical.

The expression “alkylcycloalkyl radical” refers to groups which contain both cycloalkyl and also alkyl, alkenyl or alkynyl groups in accordance with the above definitions, for example alkylcycloalkyl, alkylcycloalkenyl, alkenylcycloalkyl and alkynylcycloalkyl groups. An alkylcycloalkyl group preferably contains a cycloalkyl group comprising one or two rings having from 3 to 10 (especially 3, 4, 5, 6 or 7) ring carbon atoms and one or two alkyl, alkenyl or alkynyl group(s) having 1 or from 2 to 6 carbon atoms.

The expression “hetero(alkylcycloalkyl) radical” refers to alkylcycloalkyl groups, as defined hereinbefore, in which one or more (preferably 1, 2 or 3) ring carbon atom(s) and or carbon atom(s) has/have been replaced by an oxygen, nitrogen, silicon, selenium, phosphorus or sulfur atom (preferably oxygen, sulfur or nitrogen). A hetero(alkylcycloalkyl) group preferably has 1 or 2 ring(s) having from 3 to 10 (especially 3, 4, 5, 6 or 7) ring atoms and one or two alkyl, alkenyl, alkynyl or heteroalkyl group(s) having 1 or from 2 to 6 carbon atom(s). If there is a direct bond between the silicon atom of the silane and a hetero atom, for example oxygen, nitrogen or sulfur, of the hetero(alkylcycloalkyl) radical, this bond, and therefore the entire radical, can generally be hydrolysed. Preferably, an aryl radical according to the invention is bonded to the central silicon atom of the silane by a silicon-carbon bond and is not hydrolysable. Preferred examples of non-hydrolysable groups and radicals are alkylheterocycloalkyl, alkylheterocycloalkenyl, alkenylheterocycloalkyl, alkynylheterocycloalkyl, hetero(alkylcycloalkyl), heteroalkylheterocycloalkyl and heteroalkylheterocycloalkenyl, the cyclic groups being saturated, mono-unsaturated, di-unsaturated or tri-unsaturated.

The expression “aryl radical” refers to an aromatic group which has one or more ring(s) having especially from 6 to 14 ring carbon atoms, preferably from 6 to 10 (especially 6) ring carbon atoms. The expression “aryl radical” (or “Ar”) refers furthermore to groups in which one or more hydrogen atom(s), independently of one another, has/have been replaced in each case by a fluorine, chlorine, bromine or iodine atom or by one of the groups —COOH, —OH, —SH, —NH₂ or —NO₂. If there is a direct bond between the silicon atom of the silane and a hetero atom, for example oxygen, nitrogen or sulfur, of a correspondingly substituted aryl radical, this bond, and therefore the entire radical, can generally be hydrolysed. Examples of hydrolysable aryl radicals are a phenoxy or anilino radical. Preferably, an aryl radical according to the invention is bonded to the central silicon atom of the silane by a silicon-carbon bond and is not hydrolysable. Preferred examples of non-hydrolysable groups and radicals are the phenyl, benzyl, naphthyl, biphenyl, 2-fluorophenyl, anilinyl, 3-nitrophenyl, 4-hydroxyphenyl or pentafluorophenyl radical. Phenyl radicals are especially preferred. The use of silanes having aryl radicals such as, for example, the phenyl radical, advantageously results in the molecular sieve according to the invention having a high degree of hydrophobicity. This is presumably caused by good shielding of the hydrophilic molecular sieve surface from a solvent.

The expression “heteroaryl radical” refers to an aromatic group containing one or more ring(s) having especially from 5 to 14 ring atoms, preferably from 5 to 10 (especially 5 or 6) ring atoms, and one or more (preferably 1, 2, 3 or 4) oxygen, nitrogen, phosphorus or sulfur ring atoms (preferably oxygen, sulfur or nitrogen). The expression “heteroaryl radical” furthermore relates to groups in which one or more hydrogen atom(s), independently of one another, has/have been replaced in each case by a fluorine, chlorine, bromine or iodine atom or by one of the groups —COOH, —OH, —SH, —NH₂ or —NO₂. If there is a direct bond between the silicon atom of the silane and a hetero atom, for example oxygen, nitrogen or sulfur, of the heteroaryl radical, this bond, and therefore the entire radical, can generally be hydrolysed. Examples of a hydrolysable heterocycloalkyl radical are, for example, 1-pyridyl or N-pyrrolyl, while, for example, 2-pyridyl or 2-pyrrolyl are examples of a non-hydrolysable heterocycloalkyl radical.

The expression “arylalkyl radical” refers to groups which contain both aryl and also alkyl, alkenyl, alkynyl and/or cycloalkyl groups according to the above definitions, for example arylalkyl, alkylaryl, arylalkenyl, arylalkynyl, arylcycloalkyl, arylcycloalkenyl, alkylarylcycloalkyl and alkylarylcycloalkenyl groups. Specific examples of arylalkyls are toluene, xylene, mesitylene, styrene, benzyl chloride, o-fluorotoluene, 1H-indene, tetraline, dihydronaphthalene, indanone, phenylcyclopentyl, cumene, cyclohexylphenyl, fluorene and indan. Preferably, an arylalkyl group contains one or two aromatic ring(s) having from 6 to 10 ring carbon atoms and one or two alkyl, alkenyl and/or alkynyl groups having 1 or from 2 to 6 carbon atom(s) and/or a cycloalkyl group having 5 or 6 ring carbon atoms.

The expression “hetero(arylalkyl) radical” refers to an arylalkyl group as defined hereinbefore in which one or more (preferably 1, 2, 3 or 4) ring carbon atom(s) and or carbon atom(s) has/have been replaced by an oxygen, nitrogen, silicon, selenium, phosphorus, boron or sulfur atom (preferably oxygen, sulfur or nitrogen), that is to say groups which contain both aryl or heteroaryl and also alkyl, alkenyl, alkynyl and/or heteroalkyl and/or cycloalkyl and/or heterocycloalkyl groups according to the above definitions. Preferably, a hetero(arylalkyl) group contains one or two aromatic ring(s) having 5 or from 6 to 10 ring carbon atoms and one or two alkyl, alkenyl and/or alkynyl group(s) having 1 or from 2 to 6 carbon atom(s) and/or a cycloalkyl group having 5 or 6 ring carbon atoms, wherein 1, 2, 3 or 4 of those carbon atoms has/have been replaced by oxygen, sulfur or nitrogen atoms. Preferred examples are arylheteroalkyl, arylheterocycloalkyl, arylheterocycloalkenyl, arylalkylheterocycloalkyl, arylalkenylheterocycloalkyl, arylalkynylheterocycloalkyl, arylalkylheterocycloalkenyl, heteroarylalkyl, heteroarylalkenyl, heteroarylalkynyl, heteroarylheteroalkyl, heteroarylcycloalkyl, heteroaryl-cycloalkenyl, heteroarylheterocycloalkyl, heteroarylhetero-cycloalkenyl, heteroarylalkylcycloalkyl, heteroarylalkyl-heterocycloalkenyl, heteroarylheteroalkylcycloalkyl, heteroarylheteroalkylcycloalkenyl and heteroarylhetero-alkylheterocycloalkyl groups, the cyclic groups being saturated or mono-unsaturated, di-unsaturated or tri-unsaturated. If there is a direct bond between the silicon atom of the silane and a hetero atom, for example oxygen, nitrogen or sulfur, of the hetero(arylalkyl) radical, this bond can generally be hydrolysed. If the hetero(arylalkyl) radical is bonded to the central silicon atom of the silane by a silicon-carbon bond, the hetero(arylalkyl) radical is generally not hydrolysable.

The expressions “cycloalkyl”, “heterocycloalkyl”, “alkylcycloalkyl”, hetero(alkylcycloalkyl)”, “aryl”, “heteroaryl”, “arylalkyl” and “hetero(arylalkyl)” also refer to groups in which one or more hydrogen atom(s), independently of one another, has/have been replaced by fluorine, chlorine, bromine or iodine atoms or OH, ═O, SH, ═S, NH₂, ═NH or NO₂ groups. The expressions refer furthermore to groups which are substituted by unsubstituted C₁-C₆alkyl, C₂-C₆alkenyl, C₂-C₆alkynyl, C₁-C₆heteroalkyl, C₃-C₁₀cycloalkyl, C₂-C₉heterocycloalkyl, C₆-C₁₀aryl, C₁-C₉heteroaryl, C₇-C₁₂arylalkyl or C₂-C₁₁hetero(arylalkyl) groups.

Preferably, in each of the above-mentioned radicals all hydrogen atoms may be replaced by halogen atoms, especially by fluorine atoms. Especially when the molecular sieve according to the invention is used in a liquid phase, for example dispersed in a liquid organic compound, the use of silanes having perfluorinated radicals may be advantageous. For example when a dispersion of the molecular sieve according to the invention in a liquid organic compound is used in conjunction with machinery, for example for the purpose of its application by spraying using a spraying apparatus or for the purpose of printing using a printing apparatus or the like, the interactions between the particles of the molecular sieve coated with a silane having perfluorinated radicals and the surfaces of the apparatus in question, for example the internal surfaces of storage vessels, pipework or hoses, nozzles or the like, are advantageously minimised.

Especially preferred silanes are acetoxysilanes, acetylsilanes, acryloxysilanes, adamantylsilanes, allylsilanes, alkylsilanes, allyloxysilanes, alkenylsilanes, alkoxysilanes, alkynylsilanes, aminosilanes, azidosulfonylsilanes, benzoyloxysilanes, benzylsilanes, bromoalkylsilanes, bromoalkenylsilanes, bromovinylsilanes, alkoxycarbonylsilanes, chloroalkylsilanes, chloroalkenylsilanes, chlorovinylsilanes, cycloalkylsilanes, cycloalkenylsilanes, diphenylsilanes, ditolylsilanes, epoxysilanes, fluorinated silanes, for example fluorinated alkylalkoxysilanes, e.g. (3-heptafluoroisopropoxy)propyl-trimethoxysilanes, (CF₃)₂CF—O—C₃H₆Si(OCH₃)₃, or fluorinated alkylsilanes, e.g. (heptadecafluoro-1,1,2,2-tetrahydrodecyl)triethoxysilanes, methacryloxysilanes, naphthylsilanes, pentafluorophenylsilanes, phenylsilanes, propargylsilanes, propargyloxysilanes, silyl cyanides, silyl phosphates or vinyl silanes.

All those silane compounds may contain one or more chiral centres. The present invention accordingly comprises all pure enantiomers and also all pure diastereomers, and also mixtures thereof in any mixing ratio. Furthermore, the present invention also includes all cis/trans isomers of the compounds, and also mixtures thereof. Furthermore, the present invention includes all tautomeric forms.

The expression “hydrolysable group” herein defines especially a group which is split off on reaction with water, whereupon the terminal part of the group (that is to say that part which is remote from the central silicon atom) is separated off from the residual molecule comprising the central silicon atom and there is formed on the residual molecule comprising the central silicon atom a hydroxide function, that is to say the group —OH. In other words, a hydrolysable group as understood by the invention is preferably a potential leaving group which is split off, or released, for example on reaction with water. Hydrolysable groups of such a kind are also split off by other molecules—apart from water—which have terminal hydroxy functions (that is to say the group —OH), for example by alcohols, protonic acids, e.g. carboxylic acids, sulfur oxygen acids or phosphorus oxygen acids, or also by free hydroxy groups on the surface of oxidic solids. Preferred examples of such hydrolysable groups are radicals (R¹, R², R³ or R⁴) such as ester groups containing a carboxylic or sulfonic acid and an alcohol etc.

Preferably, the hydrolysable group comprises the entire radical, that is to say one of the groups R¹, R², R³ or R⁴, so that under hydrolysis conditions the entire radical (R¹, R², R³ or R⁴) is separated off from the residual molecule comprising the central silicon atom, and an Si—OH group is formed. Preferred examples of hydrolysable groups of such a kind, which in the context of the invention are also referred to as hydrolysable radicals, are e.g. a heteroalkyl radical such as an alkoxy radical bonded by way of the oxygen atom, having the general formula —OR, a heterocycloalkyl radical such as a piperidine radical, a heteroaryl radical such as a pyridyl or pyrrole radical, an amine radical such as —NH₂ or NMe₂, a cyanide or phosphate radical etc. Special preference is given to an alkoxy radical bonded by way of the oxygen atom, for example a methoxy, ethoxy, n-propanoxy, isopropanoxy, n-butanoxy, isobutanoxy, sec-butanoxy, tert-butanoxy or hexanoxy radical, or a phenyloxy radical or a cyanide group.

The hydrolysis reaction preferably is a reaction which proceeds spontaneously in the presence of water under normal conditions but also includes reactions which proceed under conditions of, for example, elevated temperature or in the presence of a catalyst. Preferred examples of catalysed hydrolysis reactions of such a kind are reactions which proceed in the presence of an electrophile, e.g. (protonic) acid-catalysed reactions, or those which proceed in the presence of a nucleophile, e.g. base-catalysed reactions.

In the treatment of a molecular sieve particle with a silane containing at least one hydrolysable group, the hydrolysable group can react directly with a functional group on the surface of the particle. In the process preference is given to the hydrolysable group being split off as a leaving group and a bond being formed between the surface of the particle and the silane with its remaining radicals. Such a particle is, as understood by the invention, referred to as a particle whose surface is coated with a silane. A molecular sieve according to the invention is hydrophobically coated with a silane defined hereinbefore.

Especially, during the coating reaction which results in the hydrophobically coated molecular sieve in accordance with the invention, at least one hydrolysable group of the silane is replaced by a functional group on the surface of the molecular sieve particle, as a result of which the silane, containing the remaining radicals, is joined to the surface of the molecular sieve particle. For example, the silane can react with an oxidic solid as molecular sieve particle so that at least one hydrolysable group condenses with a hydroxide group on the surface of the inorganic solid, releasing the hydrolysable group, as a result of which the silane radical, having the remaining radicals, is joined to the molecular sieve particle by way of an oxygen-silicon bond. Preferably, all the hydrolysable groups of the silane will react with functional groups of the molecular sieve particle and form corresponding bonds with the molecular sieve particle. For example, a silane having two hydrolysable groups can react with an oxidic solid as molecular sieve particle so that the two hydrolysable groups condense with two hydroxide groups on the surface of the inorganic solid, releasing the hydrolysable groups, as a result of which the silane radical, having the remaining radicals, is joined to the molecular sieve particle by way of two oxygen-silicon bonds. In that case, the two hydroxide groups on the surface of the inorganic solid are preferably two neighbouring hydroxide groups on the surface of the inorganic solid. In corresponding manner, a silane having three hydrolysable groups can react with an oxidic solid as molecular sieve particle so that the three hydrolysable groups condense with three hydroxide groups on the surface of the inorganic solid, releasing the three hydrolysable groups, as a result of which the silane radical, having the remaining radical, is joined to the molecular sieve particle by way of three oxygen-silicon bonds. In that case, the three hydroxide groups on the surface of the inorganic solid are preferably three neighbouring hydroxide groups on the surface of the inorganic solid. Preferably, a hydrophobically coated molecular sieve in accordance with the invention, which is obtained by treatment of a molecular sieve particle with a silane defined hereinbefore or is coated with a silane defined hereinbefore, contains no remaining hydrolysable groups. As understood by the invention, a hydrophobically coated molecular sieve which has been coated by treatment with a silane defined hereinbefore is also referred to as a molecular sieve which is coated with a silane. A hydrophobically coated molecular sieve in accordance with the invention, which is coated with a silane defined hereinbefore, is especially a molecular sieve which is obtainable by treatment of a molecular sieve particle with a silane.

Preferably, the silane does not contain a radical containing a functional group which reacts with the hydrolysable group under normal conditions or under the conditions which are used for coating of the particles. Such a compound is disadvantageous for the present invention because it would, for example, react with itself (e.g. polymerise) under the mentioned conditions, and would therefore no longer be available for coating the surface of the particles, or react to form a polymeric material having bound-in particles which would therefore no longer be in the form of discrete particles.

When, in the present invention, a distinction is made between radicals R¹, R², R³ or R⁴ containing a hydrolysable group and remaining radicals R¹, R², R³ and R⁴ which are, independently of one another, an alkyl, alkenyl, alkynyl, heteroalkyl, cycloalkyl, heteroaryl, alkylcycloalkyl, hetero(alkylcycloalkyl), heterocycloalkyl, aryl, arylalkyl or hetero(arylalkyl) radical, the intention thereby is to stipulate that the remaining radicals do not contain a hydrolysable group. In other words, in accordance with the invention at least one of the radicals R¹, R², R³ or R⁴ of the silane contains a hydrolysable group and the remaining radicals R₁, R₂, R₃ and R₄ are, independently of one another, a non-hydrolysable alkyl, a non-hydrolysable alkenyl, a non-hydrolysable alkynyl, a non-hydrolysable heteroalkyl, a non-hydrolysable cycloalkyl, a non-hydrolysable heteroaryl, a non-hydrolysable alkylcycloalkyl, a non-hydrolysable hetero(alkylcycloalkyl), a non-hydrolysable heterocycloalkyl, a non-hydrolysable aryl, a non-hydrolysable arylalkyl or a non-hydrolysable hetero(arylalkyl) radical, each in accordance with the definition given hereinbefore.

In accordance with the invention, at least one of the radicals R¹, R², R³ or R⁴ of the silane contains a hydrolysable group. Preferably, at least one of the radicals R¹, R², R³ or R⁴ of the silane contains a hydrolysable group selected from an alkoxy group and a cyanide group. Preferably, one, or two, or three of the radicals of the silane contain(s) a hydrolysable group and, especially, one or three of the radicals of the silane contain(s) a hydrolysable group.

In a preferred embodiment of the invention, preferably each of the hydrolysable radicals of the silane is, independently of the others, a hydrolysable alkoxy radical, and the remaining radicals are selected, independently of one another, from non-hydrolysable alkyl radicals, alkenyl radicals, alkyl radicals, cycloalkyl radicals, alkylcycloalkyl radicals, aryl radicals and arylalkyl radicals, more preferably from alkyl radicals, cycloalkyl radicals and aryl radicals, and especially from branched alkyl radicals. Special preference is given to the alkyl radicals being branched alkyl radicals having from three to eight carbon atoms.

Preferably, the silane contains one, or two, or three hydrolysable alkoxy radical(s), the remaining radicals being alkyl radicals. These silanes have the advantage that, on hydrolysis, they release the respective alkanols, which can be selected in accordance with their toxicity. Furthermore, it is advantageous that the alcohols behave inertly towards the molecular sieve under the specified conditions, that is to say do not react therewith or cannot be sorbed thereby. Preferred examples of such silanes are, e.g., isobutyltriethoxysilane, diisobutyldiethoxysilane, triisobutylethoxysilane, isobutyltrimethoxysilane, diisobutyldimethoxysilane, triisobutylmethoxysilane, isobutyldimethylmethoxysilane, isobutyldiethylmethoxysilane, isopropyltriethoxysilane, diisopropyldiethoxysilane, triisopropylethoxysilane, isopropyltrimethoxysilane, diisopropyldimethoxysilane or triisopropylmethoxysilane.

Special preference is given to the silane containing one alkyl radical and three hydrolysable alkoxy radicals. Preferred examples of such a silane are, e.g., isobutyltriethoxysilane, isobutyltrimethoxysilane, isopropyltriethoxysilane or isopropyltrimethoxysilane.

Special preference is likewise given to the silane containing three alkyl radicals and one hydrolysable alkoxy radical. Preferred examples of such a silane are, e.g., isobutyldimethylmethoxysilane or isobutyldiethylmethoxysilane.

The surface of the particles is coated with the silane, a surface region of the particle being coated with a silicon atom including its remaining, that is to say non-hydrolysed, radicals. Especially, the surface of the particles is hydrophobically coated with the silane. In the process, a surface region of the particle can also be coated with a plurality of silicon atoms; accordingly, the surface of the particle can be coated, for example, with two, three, four or five silicon atoms per surface region, in which case the silicon atoms can be arranged, for example, on top of one another in a plurality of layers or offset from one another. Preferably, the coating is a mono-layer, that is to say each surface region is coated only with exactly one silicon atom including its remaining, that is to say non-hydrolysed, radicals.

OH groups are present on the external surface of oxidic materials such as, for example, zeolites. In order to be able to disperse oxidic particles of such a kind, for example in nonpolar solvents, the OH groups located on the surface of the oxide in question are, in accordance with the invention, coated or functionalised with a silane having remaining organic groups, in which case the remaining organic groups are as similar as possible to the solvent in question. The surface of the oxide particles can accordingly be coated with nonpolar and covalently bonded groups. The formation of a covalent, chemically resistant bond is advantageous because loss of the nonpolar groups can result in the particles having an increased agglomeration tendency. It is not possible for condensation reactions to take place between the slow-to-react organic groups on the surface of a particle hydrophobically coated in accordance with the invention. Interactions between particles are therefore based mainly on van der Waals forces, which means that if two particles come into contact with one another they cannot durably and irreversibly agglomerate. Oxides hydrophobically coated or functionalised in accordance with the invention have good dispersibility in nonpolar solvents.

When an oxide is reacted with a silane defined in accordance with the invention, at least one hydrolysable group is split off and there is formed, for example, a covalent bond between the silane radical and the surface of the oxide. When, for example, the silane contains at least one hydrolysable alkoxy radical, on reaction with an oxide there is released, by hydrolysis, only the corresponding alkanol or alkyl alcohol, which can be selected, for example, according to its toxicity. An alkoxy radical as hydrolysable group or leaving group is advantageous also because alcohols generally behave inertly towards the molecular sieve under the stipulated conditions, that it so say do not react therewith or cannot be sorbed thereby.

The molecular sieve according to the invention is distinguished by its small size in the nano-scale region. This small size allows it to be used in devices of correspondingly small dimensions. For example, the molecular sieve according to the invention can be used advantageously in apparatus in which only cavities or gaps having dimensions of not more than one micrometre are available.

Furthermore, the surface of the molecular sieve according to the invention is coated with a silane, it being possible for the non-hydrolysable radicals of the silane to be so selected that they impart a desired property to the surface of the particle. Especially, the surface of the molecular sieve according to the invention is hydrophobically coated with a silane, it being possible for the non-hydrolysable radicals of the silane to be so selected that they impart the desired hydrophobic property to the surface of the particle. The person skilled in the art will know which radicals of the silane have to be selected in order to obtain a desired property for the surface. Accordingly, for example, a lipophilic or hydrophobic surface property can be obtained by silanes having non-hydrolysable alkane radicals, it being possible for the degree of the lipophilic or hydrophobic property of the surface to be modified for a particular purpose by selection of the number and features of the individual alkane radicals, e.g. the chain length or the degree of branching. A molecular sieve of such a kind can be advantageously dispersed in alkane-based organic compounds, for example in solvents, e.g. hexane or octane, or in polymers, e.g. polyethylene or polypropylene, without clump formation being observed in the material. In corresponding manner, silanes having other non-hydrolysable radicals can be used in order to obtain a surface property which makes possible dispersion in other organic compounds or materials. For example, non-hydrolysable radicals having aromatic groups can be used in order to make possible dispersion in aromatic compounds (for example aromatic solvents, e.g. benzene, toluene, xylene, pyridine, naphthalene or the like) or in compounds having aromatic groups (for example polymers having aromatic groups, e.g. polystyrene or the like), or in compounds having analogous properties to aromatic groups (for example, carbon compounds, e.g. graphite, fullerenes, carbon nanotubes or the like). Furthermore, for example, by means of a silane having a non-hydrolysable radical containing a vinyl group there can be obtained a surface which is suitable for cross-linking with vinyl-containing monomers. A molecular sieve of such a kind can be chemically bound into a polyvinyl material. Generally, by means of suitable selection of the non-hydrolysable silane radicals the surface property of the molecular sieve according to the invention can be adjusted in accordance with the intended use. Especially, by means of suitable selection of the non-hydrolysable silane radicals the hydrophobic surface property of the molecular sieve according to the invention can be adjusted in accordance with the intended use.

The terms “hydrophobically coated”, “hydrophobicised” and “hydrophobicisation” in the context of the present invention refer to surface treatment of molecular sieve particles which imparts to the produced surface a hydrophobic or lipophilic property which has the effect that the molecular sieve particle cannot be suspended or dispersed in water but can be readily suspended or dispersed in nonpolar solvents having a dielectric constant of less than 22, preferably less than 10 and especially less than 3. Accordingly, the hydrophobically coated molecular sieve is especially a molecular sieve which can be suspended or dispersed in nonpolar solvents, especially nonpolar organic solvents, which have a dielectric constant of less than 3. Examples of nonpolar organic solvents of such a kind are, for example, saturated hydrocarbons or alkanes, e.g. pentane, hexane or octane, or aromatic hydrocarbons, e.g. benzene.

In order to avoid coating and/or blocking or plugging of the pores, internal channels and cavities of the particles by the silane used in the coating of porous particles, the radicals of the silane can be so selected that the silane molecules cannot penetrate into the cavities and channels of the particles. Accordingly, a coating of solely the external surface can be achieved. The internal surface, on the other hand, remains open, that is to say is neither coated nor blocked, and so retains its original character. Accordingly, for example, a molecular sieve can be obtained which is excellently dispersible in nonpolar substances but which retains the ability to adsorb polar substances such as water. A further possibility for avoiding the pores, internal channels and cavities of the particles from being coated and/or blocked or plugged by the silane used in the coating of porous particles, is to reversibly block or reduce the size of the pores of the particles before coating with the silane, for example by loading with large ions, e.g. caesium ions or tetraalkylammonium ions.

Accordingly, for example, when it is not possible to use a silane having a molecule diameter larger than the entrance apertures of a zeolite, the entrance aperture of the zeolite can be reversibly reduced in size. In the process, the pore diameter to be established is advantageously so selected that the molecules of the silane can no longer pass into the pores. After coating, the larger pore diameter can be re-established. Such reversible adjustment of the pore diameters is carried out preferably by means of ion exchange using ions of appropriate size. Accordingly, it is known, for example, that zeolite LTA loaded with sodium has a kinetic pore diameter of 4 Å (400 pm). When loaded with potassium, on the other hand, it has a pore diameter of only 3 Å (300 pm). This ion exchange can be carried out reversibly.

The ion exchange method can also be used in order to match the refractive index of the zeolite to that of the organic compound, for example that of the polymer. This is desirable when the particle size of the zeolite introduced into a polymer is too large—in the case of a large difference in the refractive indices—to ensure optical transparency. The process of modifying the framework structure of a zeolite can also be used to match the refractive index of the zeolite to that of the organic compound in which it is to be dispersed. This is especially advantageous when the particle size of the zeolite introduced into an organic compound is too large—in the case of a large difference in the refractive indices—to ensure optical transparency. Details of modifying the framework structure are described, for example, in JP 86-120459. A possibility for modifying the refractive index by ion exchange is described, for example, in “Optical properties of natural and cation-exchanged heulandite group zeolites”, J. Palmer, M. Gunter; American Mineralogist (2000), 85(1), 225.

The small size of the molecular sieve according to the invention together with its coating adapted to the particular surroundings advantageously allows its use in especially thin layers. Furthermore, the molecular sieve can also be advantageously dispersed in an organic material, for example a polymer, an adhesive or a surface-coating composition, and the composition obtained in that manner can then be used in thin layers. Accordingly, using the molecular sieve according to the invention, layers having thicknesses of less than 5 μm can be accomplished, which is advantageous in particular in miniaturised electronic components and devices. In especially advantageous manner there can be produced layers of a composite material comprising the molecular sieve according to the invention, dispersed in an organic compound, for example a polymer, adhesive or surface-coating composition, having a layer thickness of less than 5 μm, preferably 2 μm, more preferably 1 μm and especially 0.6 μm.

A further advantage is that the molecular sieve according to the invention is also suitable for dispersion in a liquid organic compound so that the organic compound containing the molecular sieve can be processed using a customary printing nozzle, for example a jet printing nozzle. Accordingly, composite materials comprising the molecular sieve and an organic compound can, using customary printing methods, be printed on a material, for example a sensitive material which is arranged on an apparatus, e.g. a wafer of an electronic component or device. In contrast to customary molecular sieves, the molecular sieve of the present invention has the advantage that not only does it not contain any particles which, because of their size, are capable of blocking the nozzle but also it does not form any agglomerates in the organic layers, which can in turn block the nozzle.

Furthermore, investigation of the properties of the molecular sieve of the invention has shown that the molecular sieve of the present invention, compared to customary getter materials, makes possible especially good protection of sensitive materials even when it is introduced into relatively thick layers of organic compounds.

Preferably, the particles comprise inorganic particles. Inorganic particles as understood by the invention are inorganic solids, preferably inorganic oxidic solids, the expression “oxidic solid” meaning especially an inorganic compound which is present in the form of a crystalline, partially crystalline or non-crystalline solid. In addition to metal cations, comprising cations of one or more elements of the main groups or sub-groups of the periodic system, an oxidic solid of such a kind includes anions comprising oxygen atoms. Preferred examples of such anions, in addition to the oxide anion (O²⁻), the hyperoxide anion (O₂⁻) and the peroxide anion (O₂²⁻), are also anions which are based on oxides of elements of the main groups and sub-groups, for example sulfur oxide anions, phosphate anions, silicate anions, borate anions, aluminate anions, tungstate anions and the like. Such anions can be present, for example, in isolated form or be condensed in the form of, for example, chains, bands, layers, frameworks, cages or the like. Condensed anions of such a kind may include oxides of one or more elements of the main groups and sub-groups, with its being possible for a plurality of different elements to be included in one condensed anion.

OH groups are frequently present on the external surface of oxidic materials of such a kind. When an oxide material of such a kind is dispersed in water, a diversity of interactions between those OH groups and water come about. Accordingly, an oxide material of such a kind can, depending on the pH of the aqueous solution, gain or lose protons by way of the OH groups located at the surface. In addition, hydrogen bridge bonds can be formed, resulting in a water layer that adheres to the oxide material. The existence of such an adhering water layer on the oxide can result in its being possible to obtain the oxide material in the form of a stable aqueous suspension, because the individual particles of the oxide material cannot come into contact with one another and therefore cannot agglomerate either. Therefore, particles of inorganic oxidic materials of such a kind are preferably dehydrated, for example by heating under vacuum or by freeze-drying, when being used for the molecular sieve of the present invention.

Special preference is given to the particles being inorganic particles which are selected from particles which include porous aluminophosphates, porous silicoaluminoophosphates or zeolites. Preferred examples of such aluminophosphates are, e.g. AlPO-5, AlPO-8 or AlPO-18. Preferred examples of such silicoaluminophosphates are, e.g., SAPO-5, SAPO-16 or SAPO-17. Preferred examples of such zeolites are natural and synthetic zeolites, e.g. the natural zeolites gismondine and zeolite Na-P1 (GIS structure), and or the zeolites of type ABW, BEA or FAU, or the synthetic zeolites zeolite LTA (Linde Type A), zeolite F, zeolite LTL, P1, P2 and P3. Special preference is given to there being used as particles small-pore zeolites having pore diameters of less than 5 Å (500 pm), for example gismondine, zeolite F or zeolite LTA.

In a preferred embodiment of the present invention, the particles are selected from gismondine, zeolite LTA, zeolite LTF and zeolite P1, P2 or P3, and the silane contains one alkyl radical and three hydrolysable alkoxy radicals. In that case, special preference is given to particles of zeolite LTA which are coated with isobutyltriethoxysilane, with isopropyltriethoxysilane or with phenyltrimethoxysilane, and to particles of zeolite LTF which are coated with isobutyltriethoxysilane, with isopropyltriethoxysilane or with phenyltrimethoxysilane.

Those preferred embodiments constitute preferred examples of the molecular sieve according to the invention, but the person skilled in the art will understand that the molecular sieve of the present invention is not limited to those embodiments.

In accordance with the invention, the molecular sieve is used as a getter material. Accordingly, the molecular sieve according to the invention can, by virtue of its size, readily be used as getter material in miniaturised apparatus, for example in electronic components and devices. Especially, the molecular sieve according to the invention can be advantageously used in cavities which at least in one dimension have a maximum measurement of less than 1 μm, especially less than 500 nm.

Furthermore, the present invention relates to a composition comprising the molecular sieve according to the invention and an organic compound. The expression “organic compound” herein means a customary organic compound such as, for example, an organic solvent, an organic solid, an organic liquid or an organic polymer. In that context, organic solids and/or organic polymers can be present in any desired form or can be made into such a form. For example, organic polymers in the form of granules, strands, plates, films or the like, having any desired diameter or thickness, can be used.

Furthermore, the expression “organic compound” also includes a composition (composite material) which comprises one or more organic compound(s), it also being possible optionally for non-organic components, e.g. inorganic fillers, colorants, conductors or the like, to be included. Advantageously, the molecular sieve of the present invention can be so coated that the properties of the surface of the particles are brought into line with those of the organic compound, so that the molecular sieve is dispersed in the organic compound. The person skilled in the art will know which coating is suitable for which organic compound, as described hereinbefore.

Preferably, the organic compound contained in the composition comprises a polymeric compound. The expression “polymeric compound” includes all customary polymers such as, for example, homopolymers, syn- and iso-tactic polymers and heteropolymers, statistical polymers and block polymers and block copolymers. The polymeric compound includes both chain-form polymers and also two- or three-dimensionally cross-linked polymers. These polymers may be thermoplastic, elastic, thermosetting or the like. The expression “polymeric compound” also includes monomeric compounds and/or oligomeric compounds which may optionally be further polymerised. The polymeric compound can be present as pure compound, for example in solid form, or in the form of a solution or dispersion. Preferably, a polymeric compound is present in solid form, for example in the form of granules, strands, plates, films or the like, having any desired diameter or thickness.

Preferably, the polymeric compound is a thermoplastic compound. In this context, “thermoplastic” means that under the influence of heat the compound softens or liquefies reversibly (that is to say without the compound being destroyed) so that under the influence of heat the compound can be processed, for example shaped or moulded, or mixed with further components. Preferred examples of thermoplastic polymers are polyolefins, e.g. polyethylene (PE, HDPE or LDPE) or polypropylene (PP), polyoxyolefins, e.g. polyoxymethylene (POM) or polyoxyethylene, polymethylmethacrylate (PMMA), acrylonitrile-butadiene-styrene copolymer (ABS), or the like. Under the influence of heat, the molecular sieve according to the invention can be advantageously incorporated—even subsequently—into a thermoplastic compound, so that a homogeneous dispersion is formed without the polymeric compound being destroyed.

Special preference is given to the polymeric compound having a low water permeability, that is to say a water permeability of less than 0.9 g·mm/m²·d at a gradient of from 0% to 90% relative atmospheric humidity at 25° C. (wherein d=day), preferably less than 0.63 g·mm/m²·d, and especially less than 0.1 g·mm/m²·d (measured on a 100 μm-thick layer). Preferred examples of polymeric compounds of such a kind are, for example, polyolefins, e.g. polyethylene (PE)—both high-density polyethylene (HDPE) and low-density polyethylene (LDPE)—or polypropylene (PP) or the like. Such a composition comprising the molecular sieve of the invention and a polymeric compound having low water permeability exhibits the desired properties especially advantageously.

Preferably, the organic compound is a surface-coating composition, preferably an anhydrous surface-coating composition and especially a surface-coating composition which has low water permeability, that is to say a water permeability of less than 2 g·mm/m²·d at a gradient of from 0% to 90% relative atmospheric humidity (wherein d=day), preferably less than 1 g·mm/m²·d. Special preference is given to the surface-coating composition being a surface-coating composition which can be hardened by UV light. Preferred examples of such surface-coating compositions are, e.g., the surface-coating composition EPO-TEC OG 142-17, obtainable from Polytec PT GmbH, 76337 Waldbronn, Germany, or the surface-coating composition UV-Coating Polyled Barriersyst. #401, obtainable from Eques C.V., 5340 AE Oss, Netherlands, or the surface-coating composition Loctite 3301 Medical Grade, obtainable from Henkel Loctite Deutschland GmbH, 81925 Munich, Germany.

Preferably, the size of the particles is so selected that they can be homogeneously distributed in the organic compound. In order to obtain a homogeneous distribution of the particles in the compound in question it is important not only for the individual particles to be small compared to the thickness of a layer to be formed but also for them to be capable of being homogeneously dispersed. For that purpose the molecular sieve according to the invention is advantageously suitable.

In accordance with the invention, a composition comprising the molecular sieve of the invention and an organic compound is used in producing or sealing an apparatus.

Preferably, the apparatus is a packaging. Accordingly, a composition comprising the molecular sieve of the invention and an organic compound is used, in accordance with the invention, for producing or sealing a packaging for sensitive products which contain compounds or compositions which are attacked or destroyed by small molecules, for example apparatus such as electrical or electronic components or devices, or food or medicaments. In a preferred embodiment, such packagings are produced directly from a composition comprising the molecular sieve of the invention and an organic compound. For example, packagings, e.g. sealed film packagings (bags, sachets and the like) or plastics packagings, e.g. transparent packagings for food or medicaments, which comprise a top part and a bottom part which fit one on top of the other, can be produced directly from a polymer comprising the molecular sieve of the invention. In another preferred embodiment, packagings of other materials, e.g. paper, cardboard, a plastics material or polymer, metal or the like are sealed by being coated with a polymer film or film of surface-coating composition comprising the molecular sieve of the invention. In that context, the coating can be applied both to the outside of the packaging and also to the inside of the packaging, and preferably the coating is applied both to the outside of the packaging and also to the inside of the packaging. Preferably, such a coating, especially the outside, is transparent so that it is possible to read information, for example printed on cardboard packaging, through the coating layer comprising the molecular sieve. In a further preferred embodiment, packaging containers of another material, for example a plastics material, a metal or the like, are sealed with a film, a cap or the like made from a polymer comprising the molecular sieve of the invention in order to produce a complete packaging. Alternatively, such a composition comprising the molecular sieve of the invention and an organic compound can also be introduced into the interior space of a packaging made from another material, for example into the inside of a cap sealing a tubular packaging, e.g. the tubular packaging of a medicament.

Preference is likewise given to the apparatus being an electrical or electronic component or device. Preferred examples of an electrical or electronic component or device are a micro-electro-mechanical system (MEMS), for example an acceleration sensor, e.g. for an airbag, a micro-electro-optical system (MEOMS), a DMD chip, a system-on-chip (SoC), solar cells or the like. A preferred apparatus is a solar cell, especially a thin-layer solar cell, a diagnostic kit, an organic photochromic ophthalmic lens, a “flip-chip” or an OLED (organic light-emitting device), especially an organic solar cell, a CIS solar cell and an OLED. Preferably, such a device is sealed by being encapsulated in a tightly closing casing which is in turn sealed, adhesively bonded, coated or the like using the composition comprising the molecular sieve of the invention and an organic compound. Special preference is given to the casing also being made from the composition.

Alternatively, a surface to be protected is directly coated with a composition comprising the molecular sieve of the invention and an organic compound. In this context, a “surface to be protected” means a surface of an apparatus made from a material which is attacked by small molecules. The composition can be applied to the surface by any customary method, for example by pouring, immersing, spraying, surface-coating, rolling, brush application or the like. Depending on the nature of the composition, the application can also comprise further steps, for example, in the case of application of a soluble composition: dissolution in a suitable solvent before application and removal of the solvent—e.g. by evaporation—after application; in the case of application of a composition comprising a thermoplastic polymer: heating before application and cooling after application; in the case of application of a composition comprising polymerisable monomers or oligomers: initiating a polymerisation reaction after application, e.g. by UV irradiation or heating, optionally followed by removal of an optional solvent; or the like. Optionally, a step of cleaning the surface to be protected can be included prior to application of the composition.

Special preference is given to a composition which comprises the molecular sieve of the invention and an organic compound being printed, by means of a printing nozzle, on the surface to be protected. In this context, any customary printing nozzle or printing method may be used which are suitable for the application of layers by printing. For example, the composition can be printed using a customary jet printing apparatus as is used in the manufacture of wafers for electrical and/or electronic circuits and of apparatus based on such wafers. Such printing nozzles frequently have a nozzle diameter in the region of some micrometres. The composition, which comprises the molecular sieve of the present invention having particles having a particle size of 1000 nm or less, can pass through that printing nozzle without the nozzle being blocked by particles or agglomerates. This allows the composition to be advantageously applied in an automated operation, for example by a robot, which is not possible using a composition comprising a customary getter material.

In a further preferred application, a composition comprising the molecular sieve of the invention and an organic compound is used in the production of membranes.

The invention relates also to an apparatus which comprises a molecular sieve according to the invention or a composition comprising the molecular sieve of the invention and an organic compound. The expression “apparatus” herein has the meaning stipulated hereinbefore. In such an apparatus, the advantageous effects of the present invention are especially brought to the fore.

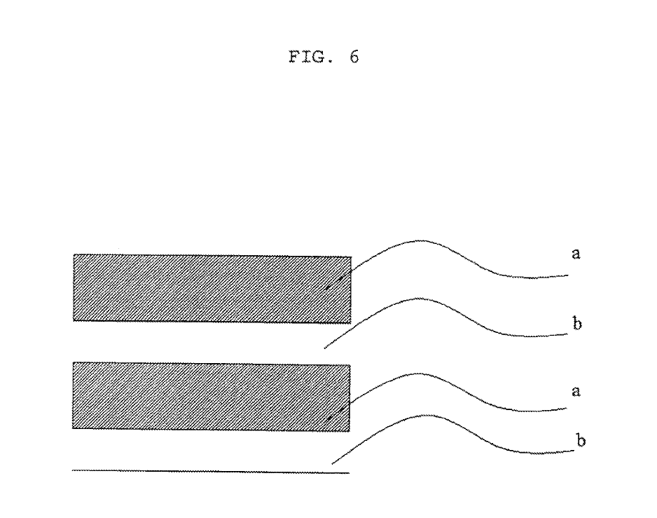

Preferably, the apparatus according to the invention comprises more than one layer of a composite material comprising the molecular sieve according to the invention and an organic compound, for example a polymer, an adhesive, a surface-coating composition or the like, especially two layers, three layers or four layers. Preferably, the layers are applied on top of one another successively. In an alternative embodiment, the layers are applied in alternation with other material layers. Preferably, those other material layers consist of sensitive materials, so that a sensitive material is laminated between two layers of the composite material according to the invention. Alternatively, other materials can also be used which, for example, fulfil a further function of the apparatus, for example a control function, an optical function or a cooling/heating function, or have a further protective function, for example against electromagnetic radiation, e.g. light, UV light or the like, or can form a diffusion barrier. Accordingly, laminate sequences can be produced which consist of a plurality of layers and which, in dependence on the layers or layer sequences in question, can result in a multiplicity of possible applications. An example of a multi-layer structure is shown in FIG. 6.

The present invention further relates to a method of producing a molecular sieve according to the invention, wherein particles having a particle size of 1000 nm or less are made to react with at least one silane of the general formula

SiR¹R²R³R⁴,

wherein at least one of the radicals R¹, R², R³ or R⁴ contains a hydrolysable group and wherein the remaining radicals R¹, R², R³ and R⁴ are, independently of one another, an alkyl, alkenyl, alkynyl, heteroalkyl, cycloalkyl, heteroaryl, alkylcycloalkyl, hetero(alkylcycloalkyl), heterocycloalkyl, aryl, arylalkyl or hetero(arylalkyl) radical.

In this context all expressions are used as defined hereinbefore.

In accordance with the invention, particles are made to react with at least one silane. Preferably, one, two, three or more silanes that are different from one another can be used in the reaction. Preference is given to particles being made to react with one silane.

In a preferred embodiment of the production method of the invention, at least one of the radicals R¹, R², R³ or R⁴ of the silane used contains a hydrolysable group which is selected from an alkoxy group and a cyanide group.

The particles used, having a particle size of 1000 nm or less, can be produced by known methods. For example, zeolite particles having a particle size of less than 1000 nm can be produced in accordance with the method described in Patent Application WO 02/40403 A1.

In accordance with the invention the particles are made to react with a silane, with all reaction conditions being included. For example, the two reactants can react with one another spontaneously when they are brought into contact with one another. In that case, the method can be carried out under suitable dilution conditions or with cooling. Depending on the slowness of the reactants to react with one another it may, however, also be necessary to introduce energy, for example in the form of electromagnetic radiation, e.g. heat, visible light or UV light, or to use a suitable catalyst. The person skilled in the art can, using his knowledge of the art, select the measures suitable in each particular case.

Preferably, the reactants are made to react in a suitable solvent. Suitable solvents are any solvent which is inert with respect to the particles and the silane. Preference is given to aprotic organic solvents, for example saturated hydrocarbons such as alkanes, e.g. hexane, heptane, octane or the like, aromatic hydrocarbons, e.g. benzene, toluene, xylene or the like, halogenated hydrocarbons, e.g. carbon tetrachloride, dichloromethane, hexafluoroethane, hexafluorobenzene or the like, dimethyl sulfoxide (DMSO), dimethylformamide (DMF) or the like.

Preferably, the reactants are made to react with one another in a solvent with heating, in which case special preference is given to boiling under reflux. Preferably, the reaction is carried out under a suitable inert protective gas, e.g. argon or nitrogen.

Preferably, in producing the molecular sieve of the invention the particles are first dried before their surface is coated with the silane. Dried particles are especially advantageously suitable for producing the molecular sieve according to the invention because undesirable molecules, e.g. water molecules, which can, for example, slow down reaction with the silane, make the reaction non-uniform or otherwise hinder it, are removed from the surface. Accordingly, a molecular sieve containing no agglomerates can advantageously be obtained. Likewise, in that manner undesirable molecules can be removed from the pores of the particles. Optionally, a cleaning step can be carried out before the drying step, in which the particles are, for example, washed using a suitable system in order to free the surface and/or the pores from undesirable loading with molecules or ions. Especially, ions present in the particles can also be exchanged by means of ion exchange reactions in order to modify the properties of the particles, e.g. the pore size, in line with the particular purpose.

Special preference is given to drying the particles by a method which is selected from heating in a vacuum and freeze-drying. For heating, the particles are heated preferably for at least 12 hours, preferably at least 24 hours and especially at least 48 hours in an electric oven under a vacuum of 10⁻² mbar at a temperature of at least 150° C., and especially at least 180° C., in order to remove undesirable molecules from the surface. In a preferred method, the particles are dried by heating before coating with the silane. In a preferred method, the particles are dried by heating after coating with the silane. Accordingly, the particles can advantageously be prevented from forming agglomerates. In an especially preferred method, the particles are dried by heating both before and also after coating with the silane.

Preferably, the particles are, in a first step, freeze-dried. For the purpose of freeze-drying, the particles are, for example for at least 12 hours, preferably at least 24 hours, and especially at least 48 hours, in an appropriate apparatus under vacuum (10⁻² mbar) at a temperature of not more than 25° C., preferably not more than 20° C., in order to remove undesirable molecules from the surface. Accordingly, it is advantageously possible for the particles not to form any agglomerates. Freeze-drying is especially advantageous when the molecular sieve is produced in aqueous suspension. This suspension can be frozen and dried by freeze-drying in order to advantageously prevent the particles from forming agglomerates. In an especially preferred method, the particles are first dried by freeze-drying, then dried by heating in a vacuum and afterwards coated with the silane. Optionally, the particles can be dried by heating in a vacuum after coating. Accordingly it is advantageously possible to prevent the particles from forming agglomerates.

In an alternative, especially preferred method, the particles are first dried by freeze-drying, then coated with the silane and, after coating, dried by heating in a vacuum. Especially when a zeolite is used as molecular sieve, it is quite crucial that the zeolite be dried by freeze-drying before coating and by heating in a vacuum after coating. It has been found that by means of this especially preferred method it is possible to prevent impairment of the product properties.

In a preferred method of producing the particles according to the invention, for coating with the silane the particles are, in a first step, suspended in a suitable solvent and, in a following step, the silane is added to that suspension. Suitable solvents are any solvent that is inert towards the particles and the silane. Preference is given to aprotic organic solvents, for example saturated hydrocarbons such as alkanes, e.g. hexane, heptane, octane or the like, aromatic hydrocarbons, e.g. benzene, toluene, xylene or the like, halogenated hydrocarbons, e.g. carbon tetrachloride, dichloromethane, hexafluoroethane, hexafluorobenzene or the like, dimethyl sulfoxide (DMSO), dimethylformamide (DMF) or the like. Preferably the silane is added in portions, e.g. by dropwise addition, optionally in admixture with solvent. Preferably, the reaction is carried out under an inert gas, e.g. argon or nitrogen.

In an alternative method of producing the particles according to the invention, for coating with the silane the silane is, in a first step, mixed with a suitable solvent and, in a following step, the particles are added. A suitable solvent is as defined hereinbefore. Preferably, the particles are added in portions, optionally in admixture with solvent. Preferably, the reaction is carried out under an inert gas, e.g. argon or nitrogen.

### EXAMPLES

### Measurement of Particle Sizes

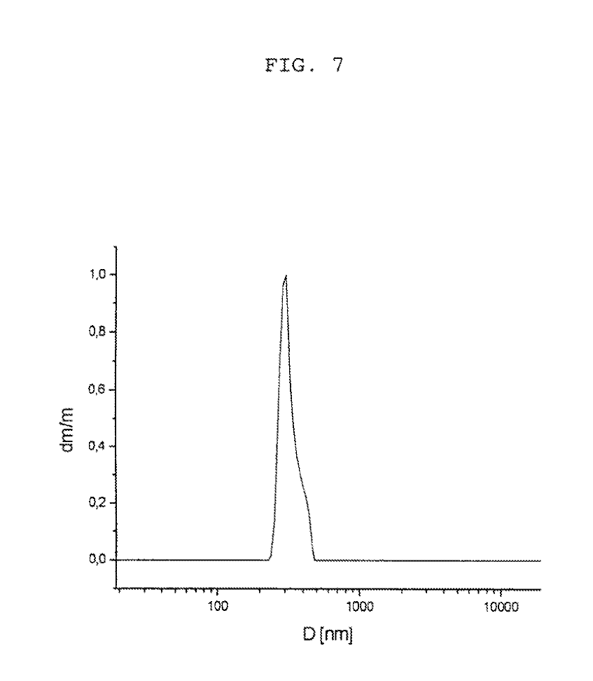

The size distributions of the molecular sieve particles were determined by means of dynamic light scattering measurements. For that purpose, in each case about 2 ml of a dispersion containing the particles to be examined in a suitable solvent or in a composition were measured using an ALV-NIBS Particle Sizer, obtainable from the company ALV-GmbH Langen. A typical size distribution is shown in FIG. 7.

Unless otherwise stated, for all the examples described hereinafter, there was used zeolite LTA having a particle size of about 300 nm (see FIG. 7), which was produced according to the method described in Patent Application WO 02/40403 A1.

### Example 1

### Coating of the Molecular Sieve

a) Coating of Zeolite LTA with Isobutyltriethoxysilane:

100 ml of a 20% aqueous suspension of zeolite LTA having a particle size of 300 nm were freeze-dried. A high cooling rate was ensured during freezing. The powder, having been dehydrated in a fine vacuum (10⁻² mbar) at a temperature of 150° C., was introduced into a mixture of 100 ml of dried toluene and 10 ml of isobutyltriethoxysilane with stirring and boiled under reflux for one hour. After cooling the mixture, the product was filtered off. A white, markedly hydrophobic powder was obtained, which is very readily dispersible in alkanes, e.g. pentane, hexane, heptane, alcohols, e.g. ethanol, isopropanol, and diethyl ether. The hydrophobicised zeolite is, in contrast, no longer dispersible in water.

b) Coating of Zeolite LTA with Phenyltrimethoxysilane:

The procedure was as in Example 1a) except that phenyltrimethoxysilane was used instead of isobutyltriethoxysilane. A white, markedly hydrophobic powder was obtained, which is very readily dispersible in o-xylene, p-xylene, toluene and benzene, but not in water.

c) Coating of Zeolite F with Isobutyltriethoxysilane:

The procedure was as in Example 1a) except that, instead of 100 ml of 20% aqueous suspension of zeolite LTA, 100 ml of a 20% aqueous suspension of zeolite F having an average particle size of 400 nm was used. A white, markedly hydrophobic powder was obtained, which is very readily dispersible in alkanes, e.g. pentane, hexane, heptane, alcohols, e.g. ethanol, isopropanol, and diethyl ether. The hydrophobicised zeolite is, in contrast, no longer dispersible in water.

### Comparison Example 1

As a comparison example, a zeolite LTA having a particle size of about 5 μm (determination by DLS) was dried and hydrophobicised in accordance with the method described in Example 1.

### Example 2

### Testing of Water Take-Up Capacity

10 g of the dehydrated and hydrophobicised zeolite of Example 1a) are introduced into 90 g of polyethylene (m.p.: about 125° C.) in an extruder. Take-up of water by the polymer composite obtained is confirmed by means of the increase in weight on storage in ambient air. Accordingly, in a week at a relative atmospheric humidity of about 40% and a temperature of about 20° C., an increase in weight of 1.3 g is ascertained.

### Example 3

### Preparation of Composite Material

2 g of the coated zeolite material according to Example 1a) are stirred into 8 g of a UV-hardening N,N-dimethylacrylamide-based adhesive (“Locktite 3301”, obtainable from Henkel Loctide Deutschland GmbH). The resulting suspension is placed in an ultrasonic bath for five minutes. The adhesive composite can be cured using UV light and used for covering over moisture-sensitive substances.

### Example 4

### Composite Material Barrier Property

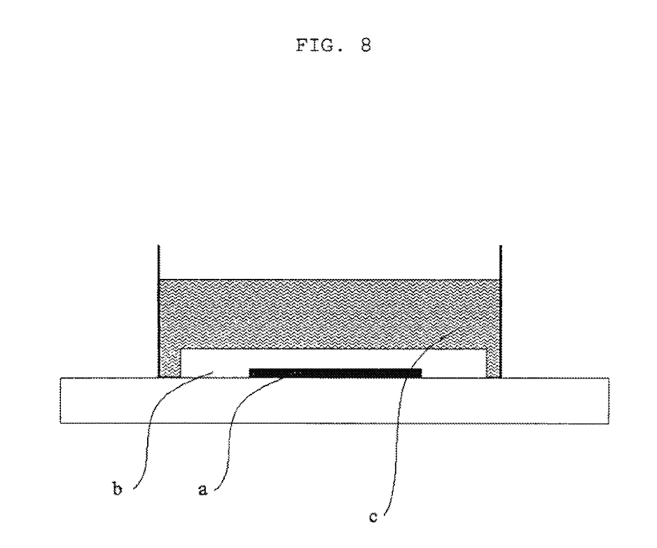

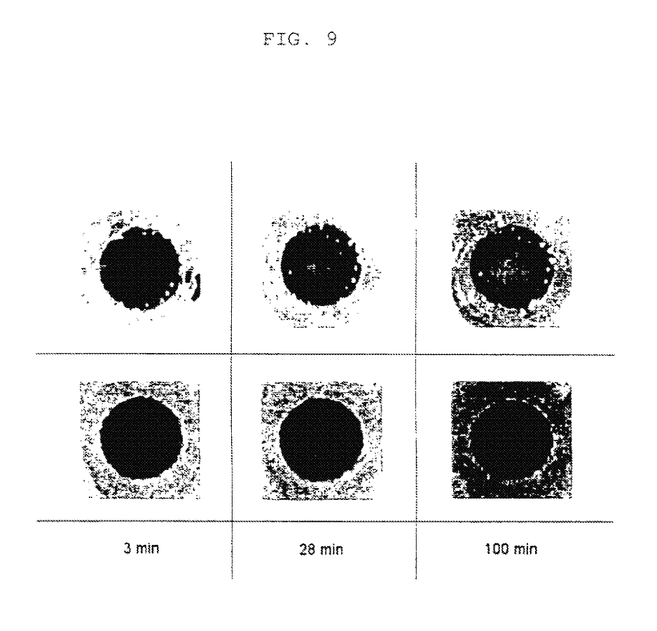

In order to test the ability to protect moisture-sensitive substances (barrier property), the test structure shown in FIG. 8 was used. In the absence of moisture, pieces of paper having a size/diameter of 15 mm and impregnated in each case with 5 mg of anhydrous, blue cobalt chloride as indicator substance are each placed on a glass plate having an area of 20 cm². Then the adhesive composition produced in Example 3 is poured over one of the glass plates so that an additional margin of 8 mm around the piece of paper impregnated with the indicator substance on the glass plate is covered by the adhesive composition and the adhesive composition is cured using UV light. In similar manner, but using a pure adhesive composition (“Locktite 3301”, obtainable from Henkel Loctide Deutschland GmbH), a comparison sample is produced. Both samples are covered with water and the changes are observed visually. Photographs of the course of the test are shown in FIG. 9. Penetration of the surface-coating composition layer by water is shown by a change in the colour of the cobalt chloride indicator from blue (dark grey in FIG. 9) to pink (light grey in FIG. 9). As can be clearly seen from FIG. 9, penetration by water is already observed in the case of the comparison sample after 28 minutes, and after 100 minutes almost the entire indicator is pink (light grey in FIG. 9), that is to say has come into contact with water. On the other hand, the sample according to the present invention shows no change of any kind during that test period, that is to say the indicator remains blue (dark grey in FIG. 9). This test shows, that the take-up of moisture by a water indicator (cobalt chloride) is markedly slowed down by the adhesive composition according to Example 3 of the present invention in comparison with untreated adhesive.

### Example 5

1 g of zeolite LTL having a particle size of, on average, 150 nm is stirred with 50 ml of concentrated CsCl solution for one hour at room temperature, filtered off, washed, redispersed in water and freeze-dried. After drying at room temperature in a fine vacuum, the zeolite is boiled for one hour under reflux with 50 ml of toluene and 5 ml of isobutyldiethylethoxysilane. After cooling, it is filtered off and washed with acetone.

The material thereby produced is introduced into 10 g of polyethylene (m.p.: about 125° C.) with a miniature extruder at a temperature of 120. The optical properties of the composite material cannot be differentiated with the naked eye from those of the polyethylene used.

### Example 6

### Calcium Mirror Test on Surface-Coating Compositions

For testing the properties of surface-coating compositions by a calcium mirror test, the following samples and comparison samples were prepared:

Sample A) Pure surface-coating composition (polymer dissolved in toluene); prepared by dissolving 20 g of TOPAS 8007 granules (obtainable from the company Ticona, of Kelsterbach) in 100 g of dry toluene.

Sample B) Surface-coating composition as in Sample A), with addition of 10% by weight of zeolite LTA having a particle size of 300 nm.

Sample C) Surface-coating composition as in Sample B), but with addition of 10% by weight of coated zeolite LTA having a particle size of 300 nm in accordance with Example 1a).

Sample D) Surface-coating composition as in Sample B), but with addition of 10% by weight of coated zeolite LTA having a particle size of 5 μm.

Calcium was vapour-deposited in a vacuum method onto four glass slides. After vapour deposition, the slides were each coated with one of the surface-coating compositions of Samples A) to D) in an immersion method in the absence of moisture, the drawing rate being a constant 2 cm/s. The slides coated with the surface-coating compositions of Samples A) to D) were dried for two days at room temperature in an inert atmosphere (argon, 99.999%).

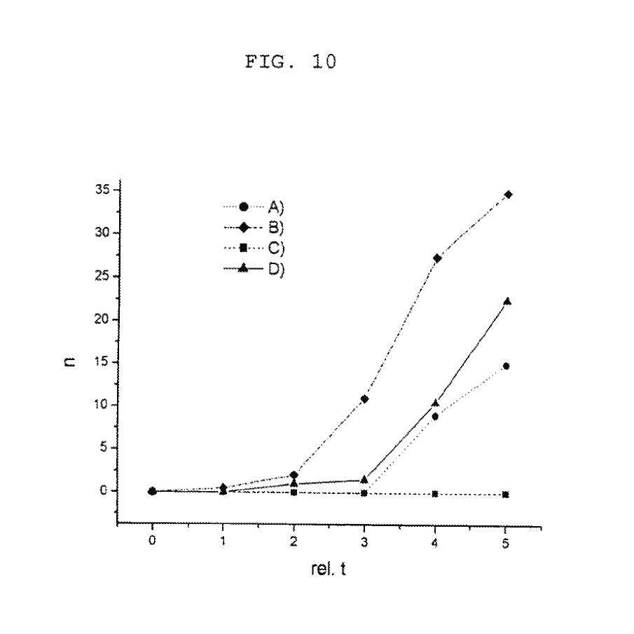

The surface-coating composition on one side of each of the coated and dried slides was then scratched off using a knife. The reverse sides of the slides, each of which at time 0 exhibited a complete mirror surface, were stored for several days in the ambient atmosphere (air) and examined and compared. In the case of slides B) and D), pointwise cloudiness of the mirror was rapidly observed, whereas in the case of slide A) a large number of small cloudy areas were observed after some time. Slide C) was the longest in exhibiting no impairment of the mirror. FIG. 10 shows the data obtained.

In order to compensate for the variation in the humidity of the atmosphere, the data was plotted against a relative time axis. The results are compiled in Table 1, the life of the calcium mirror being given as the time for which no visible cloudiness occurs. The experiment shows that the addition of coated zeolite according to the invention results in a longer life for the calcium mirror (Sample C). The addition of non-coated zeolite of the same size (Sample B) and also the use of coated zeolite having a larger particle size of about 5 micrometres (Sample D) result in a reduced life. It is striking that the addition of uncoated zeolite particles having a particle size of 300 nm (Sample B) and the addition of larger, coated zeolite particles (Sample D) both result in impairment of the barrier property of the surface-coating composition used. The significant improvement of the barrier property by the zeolite according to the invention is therefore all the more surprising.

TABLE 1

| | | | Zeolite particle | Relative |
|---|---|---|---|---|
| Sample | Zeolite | Coating | size [μm] | life |
| A | — | — | — | 3 |
| B | LTA | No | 300 | 1 |
| C | LTA | Yes | 300 | >5 |
| D | LTA | Yes | 5000 | 1 |

### Example 7

### Transparent Films

For testing the properties of films, the following samples and comparison samples were prepared:

Sample E) 1000 g of polyethylene granules (m.p.: about 116° C.) having a particle size of about 400 μm were processed, using a twin-screw extruder having a slot die, to form a band about 30 mm wide and 1 mm thick. From the extruded material there were produced, on a hot press at 200° C., films having a thickness of 100 μm.

Sample F) 100 g of zeolite LTA having an average particle size of 300 nm were added to 900 g of polyethylene granules having a particle size of about 400 μm. The resulting mixture was processed 200° C., using a twin-screw extruder having a round die, into a polymer strand having a diameter of about 2 mm. After cooling, the polymer strand was shortened to produce granules. The resulting granules were processed in the same manner as described in Sample A) to form films.

Sample G) Films were produced in the same manner as described in the case of Sample F) except that, instead of 100 g of zeolite LTA, there were used 100 g of coated zeolite LTA having a particle size of 300 nm, which was produced in Example 1a).

Sample H) Films were produced in the same manner as described in the case of Sample F) except that, instead of 100 g of zeolite LTA, there were used 100 g of coated zeolite LTA having a particle size of about 5000 nm (about 5 μm), which was produced in the same way as Example 1).

The film samples E)-H) produced in that manner were subjected to both visual and also tactile testing. The results are compiled in Table 2.

TABLE 2

| | Zeolite particle | | Transparency | Roughness |
|---|---|---|---|---|
| Sample | size [μm] | Coating | of film | of film |
| E | — | — | Transparent | Smooth |
| F | 300 | No | Cloudy | Rough |
| G | 300 | Yes | Almost | Smooth |
| | | | transparent | |
| H | 5000 | Yes | Cloudy | Smooth |

Sample E), which contains no zeolite, serves as comparison for the properties of a conventional film, e.g. transparency and roughness. Film E) is completely transparent when looked through and it has a smooth feel. The Comparison Example Sample F) comprises nanozeolite LTA having a particle size of 300 nm. However, the zeolite is not coated and accordingly has only poor dispersibility in the nonpolar polymer. Formation of agglomerates occurs. The agglomerates result in a noticeably rough film. In some areas the agglomerates are visible to the naked eye. Film G) comprises zeolite LTA having a particle size of 300 nm coated with isobutyl radicals in accordance with the invention. The film is very similar to the comparison film E). It is just as smooth and its transparency can hardly be differentiated from the latter. Film H) comprises coated zeolite LTA, but with a particle size of about 5 micrometres. Although film H) has a smooth feel it is substantially cloudier than film E) and film G).

1. An electronic device comprising:
molecular sieve as a getter material, wherein the molecular sieve is a hydrophobically coated molecular sieve comprising particles of a particle size of 1000 nm or less, the surface of the particles coated with a silane having the general formula:
SiR¹R²R³R⁴,
wherein two or three of the radicals R¹, R², R³ or R⁴ being, independently of the others, a hydrolysable alkoxyl radical, and the remaining radicals R¹, R², R³ and R⁴ being, independently of the others, selected from the group consisting of: non-hydrolysable unsubstituted alkyl radicals, alkenyl radicals, alkynyl radicals, cycloalkyl radicals, alkylcycloalkyl radicals, aryl radicals, arylalkyl radicals,
wherein the particles comprise inorganic particles selected from particles which comprise porous aluminophosphates, porous silicoaluminophosphates or zeolites.

2. The electronic device according to claim 1, wherein each of the hydrolysable radicals of the silane is, independently of the others, a hydrolysable alkoxy radical, and the remaining radicals are non-hydrolysable alkyl radicals.

3. The electronic device according to claim 1, wherein the alkyl radicals are branched alkyl radicals having from three to eight carbon atoms.

4. The electronic device according to claim 1, wherein the particles are selected from zeolite Na-P1 (GIS structure), zeolite F, and zeolite LTA, and the silane contains one alkyl radical and three hydrolysable alkoxy radicals.

5. The electronic device according to claim 1, further comprising:
a composition comprising: the molecular sieve and an organic compound.

6. The electronic device according to claim 5, wherein the organic compound comprises a polymeric compound.

7. The electronic device according to claim 6, wherein the polymeric compound is thermoplastic.

8. The electronic device according to claim 6, wherein the polymeric compound has a water permeability of less than 0.9 g·mm/m²·d at a gradient of from 0% to 90% relative atmospheric humidity.

9. The electronic device according to claim 5, wherein the electronic device is produced or sealed using the composition.

10. The electronic device according to claim 1, wherein the electronic device is selected from a MEMS or an OLED.

11. The electronic device according to claim 5, wherein a surface of the device to be protected is directly coated with the composition.
